(19) United States
(12) Patent Application Publication
(10) Pub. No.: US 2025/0056940 A1
(43) Pub. Date: Feb. 13, 2025

(54) Phosphor Converted LEDS With Improved Light Uniformity Including Discrete Light-Scattering Layers

(71) Applicant: Lumileds LLC, San Jose, CA (US)

(72) Inventor: Hisashi Masui, Newark, CA (US)

(73) Assignee: Lumileds LLC, San Jose, CA (US)

(21) Appl. No.: 18/717,514

(22) PCT Filed: Dec. 5, 2022
(86) PCT No.: PCT/US2022/080904

§ 371 Date: Jun. 7, 2024

Related U.S. Application Data
(60) Provisional application No. 63/288,104, filed on Dec. 10, 2021.

(51) Int. Cl. H01L 33/58; H01L 25/075; H01L 33/50; H01L 33/60

(52) U.S. Cl. CPC H01L 33/58; H01L 25/0753; H01L 33/50; H01L 33/60; H01L 2933/0041; H01L 2933/0058; H01L 2933/0091

(57) ABSTRACT

Light emitting devices comprise: one or more light emitting diode (LED) dies in a reflector cup; a first light-scattering layer contacting side surfaces of the LED dies, and a bottom wall and a sidewall of the reflector cup, the first light-scattering layer comprising light-scattering particles and a first binder material; and a second light-scattering layer contacting at least a top surface of the LED dies, and the first light-scattering layer at an interface, the second light-scattering layer comprising phosphor particles and a second binder material.

### TECHNICAL FIELD

The present disclosure relates generally to light emitting diode (LED) devices in reflector cups. The LED devices comprise one or more LED dies in a reflector cup, and discrete layers, which are at least light-scattering. Among the discrete light-scattering layers, there is at least one phosphor-containing layer that provides wavelength conversion. A first light-scattering layer comprises light-scattering particles and a first binder material; and a second light-scattering layer comprises phosphor particles and a second binder material.

### BACKGROUND

Semiconductor light-emitting devices or optical power emitting devices (such as devices that emit ultraviolet (UV) or infrared (IR) optical power), including light emitting diodes, resonant cavity light emitting diodes, vertical cavity laser diodes, and edge emitting lasers, are among the most efficient light sources currently available. Due to their compact size and lower power requirements, for example, semiconductor light or optical power emitting devices (referred to herein as LEDs for simplicity) are attractive candidates for light sources, such as camera flashes, for hand-held battery-powered devices, such as cameras and cell phones. They may also be used, for example, for other applications, such as for automotive lighting, torch for video, and general illumination, such as home, shop, office and studio lighting, theater/stage lighting and architectural lighting.

High-intensity/brightness light emitting devices capable of operation across the visible spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a growth substrate such as a sapphire, silicon carbide, III-nitride, or other suitable substrate by metal-organic chemical vapor deposition (MOCVD), molecular beam epitaxy (MBE), or other epitaxial techniques. Sapphire is often used as the growth substrate due to its wide commercial availability and relative ease of use. The stack grown on the growth substrate typically includes one or more n-type layers doped with, for example, Si, formed over the substrate, a light emitting or active region formed over the n-type layer or layers, and one or more p-type layers doped with, for example, Mg, formed over the active region. An LED die is a structure including a substrate and the stack of semiconductor layers.

Phosphor converted LEDs (pc-LEDs) generally include a phosphor layer on the LED die. The phosphor layer absorbs energy and converts an entering wavelength to a lower-energy wavelength. For example, the phosphor layer down-converts high energy LED light into a more desirable color spectrum. In practice, the phosphor layer composition and structure is chosen to meet desired performance criteria.

In some packaged devices that include a plurality of LED dies or pumps located in a reflector cup, e.g. mid-power, low-power, and chip on board devices (COBs), dispensed phosphor coats the LED die on its top and sides and fills the reflector cup. Such devices can suffer from light intensity variations across the device due to light-path length differences to an exit of the device from on top of the die and from a side of the die. The light emitted from the side has longer path to the exit and thus tends to dim by various absorption mechanisms.

There is a need to reduce side light dimming in packaged devices.

### SUMMARY

Provided herein are LED devices and light sources and methods of making them.

In a first aspect, light emitting devices comprise: a light emitting diode (LED) die in a reflector cup; a first light-scattering layer contacting a side surface of the LED die, and a bottom wall and a sidewall of the reflector cup, the first light-scattering layer comprising light-scattering particles and a first binder material; and a second light-scattering layer contacting at least a top surface of the LED die and the first light-scattering layer at an interface, the second light-scattering layer comprising phosphor particles and a second binder material.

Another aspect includes: light sources comprising: one or more light emitting diode (LED) dies in a reflector cup; a first light-scattering layer contacting side surfaces of the one or more LED dies, and a bottom wall and a sidewall of the reflector cup, the first light-scattering layer comprising light-scattering particles and a first binder material; and a second light-scattering layer spanning a width of the reflector cup, and the first light-scattering layer at an interface, the second light-scattering layer comprising phosphor particles and a second binder material; wherein a combination of the first light-scattering layer and the second light-scattering layer fills the reflector cup around the one or more LED dies; and the light-scattering particles of the first light-scattering layer and the phosphor particles of the second light-scattering layer are the same material, and a first concentration of the particles of the first light-scattering layer is less than a concentration of the particles of the second light-scattering layer.

A further aspect provides: A method of manufacturing a light emitting device comprising: positioning one or more light emitting diode (LED) dies in a reflector cup; dispensing a first light-scattering composition into the reflector cup, contacting side surfaces of the one or more LED dies, and a bottom wall and a sidewall of the reflector cup, the first light-scattering layer comprising light-scattering particles and a first binder material; partially curing the first light-scattering composition to form an intermediate first light-scattering formation; dispensing a second light-scattering composition into the reflector cup, the second light-scattering composition comprising phosphor particles and a second binder material; and curing the intermediate first light-scattering formation and the second light-scattering composition to form a first light-scattering layer and a second light-scattering layer, respectively, and an interface therebetween.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The line drawings herein are not to scale.

FIG. 1 is a cross-section schematic view of a light emitting diode (LED) device according to the prior art;

FIGS. 2-3 are cross-section schematic views of light emitting diode (LED) devices according to one or more embodiments;

FIG. 4 is a cross-section schematic view of a light source according to one or more embodiments;

FIG. 5 is a process flow diagram of a method of making a light emitting device according to one or more embodiments;

FIG. 6 provides a graph of efficacy (lm/W) versus current (mA) for Comparative A and Example 1 at 25° C.;

FIG. 7 is a top view photograph of the LED device of Comparative A;

FIG. 8 is a top view photograph of the LED device of Example 1 after the first light-scattering composition is partially cured;

FIG. 9 is a top view photograph of the completed LED device of Example 1;

FIG. 10 is a graph of Δu′ versus Zenith angle (°) for Comparative A and Example 1; and

FIG. 11 is a graph of Δv′ versus Zenith angle (°) for Comparative A and Example 1.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate, or on a substrate with one or more films or features or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN and alloys), metal alloys, and other conductive materials, depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed are also performed on an underlayer formed on the substrate, and the term “substrate surface” is intended to include such underlayer as the context indicates. Thus for example, where a film/layer or partial film/layer has been deposited onto a substrate surface, the exposed surface of the newly deposited film/layer becomes the substrate surface.

Methods of depositing thin films include but are not limited to: sputter deposition, atomic layer deposition (ALD), chemical vapor deposition (CVD), physical vapor deposition (PVD), plasma enhanced atomic layer deposition (PEALD), plasma enhanced chemical vapor deposition (PECVD), and combinations thereof.

Reference to LED refers to a light emitting diode that emits light when current flows through it.

Phosphor layers absorb energy, converting an entering wavelength to a lower-energy higher wavelength, and scatter light. Herein, the phosphor layers comprise phosphor particles as down-converter material. Other down-converter materials may be semiconductor nanoparticles (quantum dots), which may be used in combination with phosphor particles.

Light emitted from a side of an LED pump or die, e.g., blue light, has a longer light path in a package than light emitted from a top of the die until the light exits the package. This long path tends to diminish intensity of the side light. Since color targeting is accomplished by phosphor on top of the die, phosphor in the side light path advantageously can be reduced so that absorption can also be reduced. In this way top light and side light have closer effective optical path lengths and light emitted from a package appears less nonuniform. The use of a single phosphor slurry to coat the LED pump or die using conventional phosphor configurations and dispensing techniques results in a long optical path for side light. Advantageously, a configuration that uses multiple light-scattering layers, at least one of which includes a phosphor-containing top layer helps to reduce the optical path for side light. Methods include using at least two discrete steps during the dispensing techniques. Conventional dispense tools can readily be adapted to the inventive dispensing techniques to solve the issue of long optical path for side light.

Generally, embodiments herein include two layers of different light-scattering compositions in the reflector cup. For example, a diluted form of a traditional phosphor layer composition may be used as a first layer in a bottom of the reflector cup to below a surface of the LED die, and the traditional phosphor layer composition may be used on top of the diluted composition as a second layer. For example, a phosphor composition use for the first layer may be diluted by silicone to be used for the second layer. Slight loading balance adjustment may be required between the two for the final color targeting. Other layer compositions may vary the type of light-scattering particle, so long as the top layer includes phosphor particles. The first slurry may be loaded scattering powders (e.g. titania, sapphire, alumina, etc.) rather than luminescing powder (e.g. phosphor).

Techniques to achieve the embodiments herein generally include: conventional preparation of an LED die (which includes a stack of semiconductor layers including an active region on a substrate) in a reflector cup, for example, on a tile or substrate of the product (e.g. mid-power lead frame); a first composition (e.g., a diluted phosphor composition) is dispensed to a partial fill (e.g., halfway) in the cup below a top surface of the LED die; the first composition is partially (e.g., snap) cured; optionally a light-up color test is conducted; a second composition (e.g., a traditional phosphor composition) is dispensed to cover the top surface of the LED die and fully fill the cup; and thereafter optionally another light-up color test is conducted.

The filling level of the first/bottom layer is lower than the package top surface. The bottom layer does not have to maintain flat profile at its surface. The filling level of the top/second layer can be either lower, equal to, or higher than the package top surface. A clear lens can be added to the package if desired.

The top layer has a primary function of achieving the desired color performance (i.e. CCT, CRI). The bottom layer is tuned in such a way to maximize the package performance (i.e. efficiency, color over angle, etc.). The number of LED dies in a package is not limited to one. A package can have multiple LED dies.

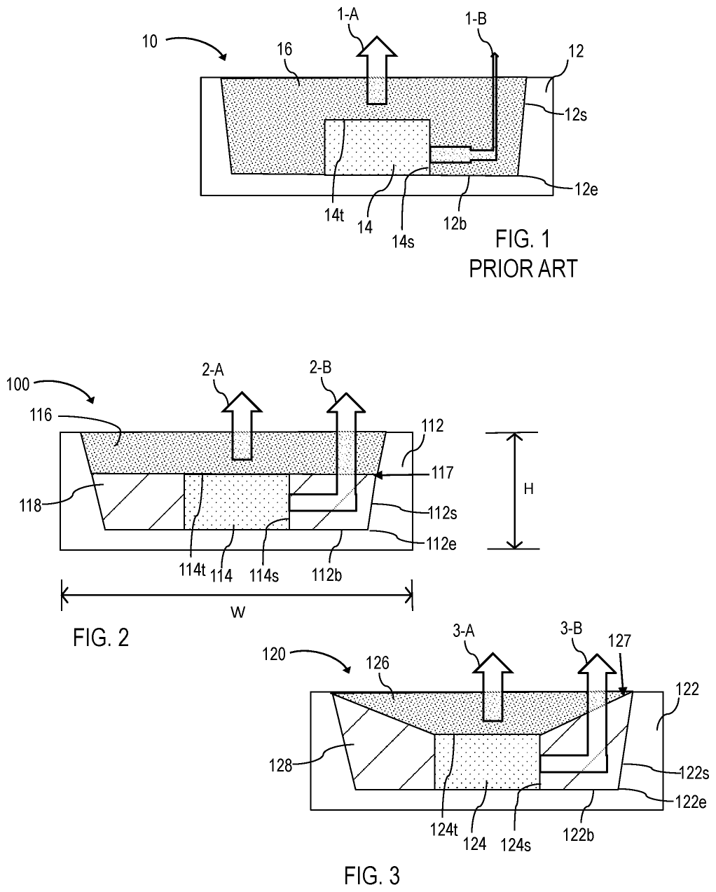

FIG. 1 is a cross-section schematic view of a light emitting diode (LED) device 10 according to the prior art. A reflector cup 12 comprises a sidewall 12s and a bottom wall 12b, which meet at a cup edge 12e. A light emitting diode (LED) die 14, also known as a pump LED, is positioned in the reflector cup 12, encased by a phosphor layer 16. Arrows 1-A and 1-B show paths of emitted light. Arrow 1-A depicts that there is a strong emission of light from a top 14t surface of the LED die 14. Arrow 1-B depicts that there is a diminished emission of light from a side surface 14s of the LED die 14. In FIG. 1, while a color target is dominated by phosphor positioned above the top surface 14t of the LED die 14, side light from the side surface 14s is diminished due to a long optical path. Similar diminishment is also observed with reflector cups having sidewalls whose intersection that are further angled such that the cup edge is closer to the LED die and there is less volume of phosphor material for the phosphor layer in the cup relative to FIG. 1.

FIG. 2 is a cross-section schematic view of a light emitting diode (LED) device 100 according to one or more embodiments. A reflector cup 112 comprises a sidewall 112s and a bottom wall 112b, which meet at a cup edge 112e. The reflector cup 112 has a width (W) spanning the cup from side-to-side, and a height (H) spanning the cup from top-to-bottom.

An LED die 114 is positioned in the reflector cup 112. The LED die 114 has a top surface 114t and a side surface 114s. A first light-scattering layer 118 contacts the side surface 114s of the LED die 114, and the bottom wall 112b and the sidewall 112s of the reflector cup 112. The first light-scattering layer 118 comprises light-scattering particles and a first binder material. A second light-scattering layer 116, which includes phosphor particles, is above the first light-scattering layer 118 and the top surface 114t of the LED die 114. In one or more embodiments, the second light-scattering layer 116 contacts at least the top surface 114t of the LED die 114, and the first light-scattering layer 118 at an interface 117. The second light-scattering layer 116 comprises phosphor particles and a second binder material.

Arrows 2-A and 2-B show paths of emitted light. Arrows 2-A and 2-B both depict that there is a strong emission of light. Advantageously, embodiments herein maintain a side light intensity by including the first light-scattering layer 118, which minimizes light absorption and facilitates light emission and/or extraction. In one or more embodiments, phosphor-loading is lower in the first light-scattering layer 118 relative to the second light scattering layer 116. Composition of the second light-scattering layer 116, e.g., phosphor loading, is chosen according to application. In one or more embodiments, color targeting of the application defines the composition of the second light-scattering layer.

Arrow 2-A represents light emission from the top 114t surface of the LED die 114. Arrow 2-B represents light emission from the side surface 114s of the LED die 114. In FIG. 2, the color target is dominated by the phosphor-containing second light-scattering layer 116 positioned above the top surface 114t of the LED die 114, side light from the side surface 114s is conveyed through the first light-scattering layer with minimal diminishment.

FIG. 3 is a cross-section schematic view of a light emitting diode (LED) device 120 according to one or more embodiments. This embodiment is a variation of FIG. 2 in that due to fluid viscosity, the 2-layer structure may have a nominally angled interface 127. A reflector cup 122 comprises a sidewall 122s and a bottom wall 112b, which meet at a cup edge 122e. An LED die 124 is positioned in the reflector cup 122. The LED die 124 has a top surface 124t and a side surface 124s. A first light-scattering layer 128 contacts the side surface 124s of the LED die 124, and the bottom wall 122b and the sidewall 122s of the reflector cup 122. A second light-scattering layer 126, which includes phosphor particles, contacts at least the top surface 124t of the LED die 124, and the first light-scattering layer 128 at the interface 127.

Arrows 3-A and 3-B show paths of emitted light. Analogous to FIG. 2, arrows 3-A and 3-B of FIG. 3 both depict that there is a strong emission of light. Advantageously, embodiments herein maintain a side light intensity by including the first light-scattering layer 128, which minimizes light absorption and facilitates light emission and/or extraction. In one or more embodiments, phosphor-loading is lower in the first light-scattering layer 128 relative to the second light scattering layer 126. Composition of the second light-scattering layer 126, e.g., phosphor loading, is chosen according to application. In one or more embodiments, color targeting of the application defines the composition of the second light-scattering layer.

Arrow 3-A represents light emission from the top 124t surface of the LED die 124. Arrow 3-B represents light emission from the side surface 124s of the LED die 124. In FIG. 3, the color target is dominated by the phosphor-containing second light-scattering layer 126 positioned above the top surface 124t of the LED die 124, side light from the side surface 124s is conveyed through the first light-scattering layer with minimal diminishment.

With respect to both FIGS. 2-3, generally, a combination of the first light-scattering layer and the second light-scattering layer fills the reflector cup around the LED die. As shown, the second light-scattering layer contacts the top surface of the LED die. It is understood that the first light-scattering layer could migrate slightly go over the top surface of the die during manufacture, making a thin film of the first light scattering material on the die. The first layer material is diluted, so it has only minimal effects even if positioned on top of the die as a very thin film. As such, the second light-scattering layer can go on top of the first-layer thin film as a whole In one or more embodiments. In one or more embodiments, the second light-scattering layer, which includes phosphor particles, is above the top surface of the LED die and/or the first light-scattering layer. In one or more embodiments, the second light-scattering layer, which includes phosphor particles, contacts at least the top surface of the LED die. In one or more embodiments, the second light-scattering layer contacts the side surface of the LED die. In one or more embodiments, the first light-scattering layer contacts both the top and side surfaces of the LED die, and the second light-scattering layer contacts the first light-scattering layer. In one or more embodiments, the second light-scattering layer contacts a part of the side surface of the LED die, but not entirely as the first layer contacts the side surface mostly if not entirely.

In one or more embodiments, the reflector cup has an aspect ratio (width to height) of in a range of 2.5:1 to 60:1, and all values and subranges therebetween, including a range of 2.5:1 to 4:1, and 2.5:1 to 10:1, and 10:1 to 60:1. In one or more embodiments, the second light-scattering layer spans the width of the reflector cup along the interface with the first light-scattering layer. In one or more embodiments, widths of the reflector cups range from 0.625 to 35 millimeters, including all values and subranges therebetween. In one or more embodiments, heights of the reflector cups range from 0.25 to 1 millimeters, including all values and subranges therebetween.

In embodiments, the first light-scattering layer and the second light-scattering layer differ in order to facilitate light emission from the side surfaces of the LED die. One or more of the following characteristics may differ between the two layers: kinematic viscosity at 25° C.; refractive index; type of particles: the light-scattering particles of the first light-scattering layer and the phosphor particles of the second light-scattering layer are different materials; type of binder material: the first binder of the first light-scattering layer and the second binder material of the second light-scattering layer are different materials; and particles loading: a first weight or volume ratio of the light-scattering particles of the first light-scattering layer to the first binder material differs from a second weight or volume ratio of the phosphor particles of the second light-scattering layer to the second binder material.

Advantageously, the first light-scattering layer and the phosphor particles of the second light-scattering layer can be the same material, which simplifies processing and implementation. When the first light-scattering layer includes phosphor particles, the first light-scattering layer provides some light conversion functionality as well. In one or more embodiments, the light-scattering particles of the first light-scattering layer and the phosphor particles of the second light-scattering layer are the same material, and a first concentration of the particles of the first light-scattering layer is less than a concentration of the particles of the second light-scattering layer. In one or more embodiments, a second composition sourced for the second light-scattering layer is diluted by an amount in a range of one-half to one-tenth to prepare a first composition sourced for the second light-scattering layer. Dilution values include all values and sub-ranges between one-half to one-tenth, including one-third.

In one or more embodiments, the first and second binder materials are the same material. In one or more embodiments, the first and second binder materials independently comprises a silicone polymer.

In one or more embodiments the light-scattering particles of the first light-scattering layer and the phosphor particles of the second light-scattering layer are different materials. In one or more embodiments, the light-scattering particles of the first light-scattering layer are non-phosphor particles. In one or more embodiments, the first light-scattering layer excludes phosphor particles.

In embodiments, the light-scattering particles of the first light-scattering layer may comprise one or more of: silica, titania, sapphire, and alumina. In embodiments, the phosphor particles of the second light-scattering layer comprise yellow-emitting wavelength converting material, or green and red emitting wavelength converting materials. In one or more embodiments, the light-scattering particles of the first light-scattering layer may comprise one or more of: silica, titania, sapphire, and alumina; and the phosphor particles of the second light-scattering layer comprise yellow-emitting wavelength converting material, or green and red emitting wavelength converting materials.

In one or more embodiments, the LED die emits blue light and wherein the phosphor particles of the second light-scattering composition emits a light that, combined with the blue light, creates a white light.

In one or more embodiments, a thickness of the phosphor-containing second light-scattering layer is in a range of 0.1 to 5 millimeters.

Binder materials of either layer could be organic-based or inorganic-based. Exemplary organic-based binder materials include but are not limited to silicone polymers (polysiloxane or polydialkylsiloxanes). Exemplary inorganic-based binder materials include but are not limited to dielectric material (e.g., silica).

In embodiments, the light-scattering layer(s) may be formed for use with a semiconductor structure that emits blue light. In such embodiments, the phosphor particles may include, for example, particles of a yellow emitting wavelength converting material or green and red emitting wavelength converting materials, which will produce white light when the light emitted by the respective phosphors combines with the blue light emitted by the light emitting semiconductor structure. In other embodiments, the phosphor layer may be formed for use with a semiconductor structure that emits UV light. In such embodiments, the phosphor particles may include, for example, particles of blue and yellow wavelength converting materials or particles of blue, green and red wavelength converting materials. Phosphor particles emitting other colors of light may be added to tailor the spectrum of light emitted from the LED.

In embodiments, the second light-scattering phosphor-containing layer may include a blend of any of the above-described phosphors.

The LED dies can be formed from an epitaxially grown or deposited semiconductor layers. A semiconductor n-layer can be formed on a growth substrate. A semiconductor p-layer can then be sequentially grown or deposited on the n-layer, forming an active region at the junction between layers. Semiconductor materials capable of forming high-brightness light emitting devices can include, but are not limited to, Group III-V semiconductors, particularly binary, ternary, and quaternary alloys of gallium, aluminum, indium, and nitrogen, also referred to as III-nitride materials. The semiconductor layers may be formed from III-V semiconductors including, but not limited to, AlN, AlP, AlAs, AlSb, GaN, GaP, GaAs, GaSb, InN, InP, InAs, InSb, II-VI semiconductors including, but not limited to, ZnS, ZnSe, CdSe, CdTe, group IV semiconductors including, but not limited to Ge, Si, SiC, and mixtures or alloys thereof. These example semiconductors have indices of refraction ranging from about 1.7 to about 4.1 at the typical emission wavelengths of LEDs in which they are present.

Substrates may be formed of any suitable material, including but not limited to sapphire and/or silicon carbide.

Direction, beam width, and beam shape of light emitted from each LED die can be modified by optical elements. The optical elements a single optical element or a multiple optic elements. Optical elements can include converging or diverging lenses, aspherical lens, Fresnel lens, or graded index lens, for example. Other optical elements such as mirrors, beam diffusers, filters, masks, apertures, collimators, or light waveguides are also included. Optical elements can be positioned at a distance from the LEDs that allows receipt and redirection of light from multiple LEDs. Alternatively, optical elements can be set atop each LED to individually guide, focus, or defocus emitted LED light. Optical elements can be directly attached to the LEDs, attached to LEDs via a transparent interposer or plate, or held at a fixed distance from LEDs by surrounding substrate attachments.

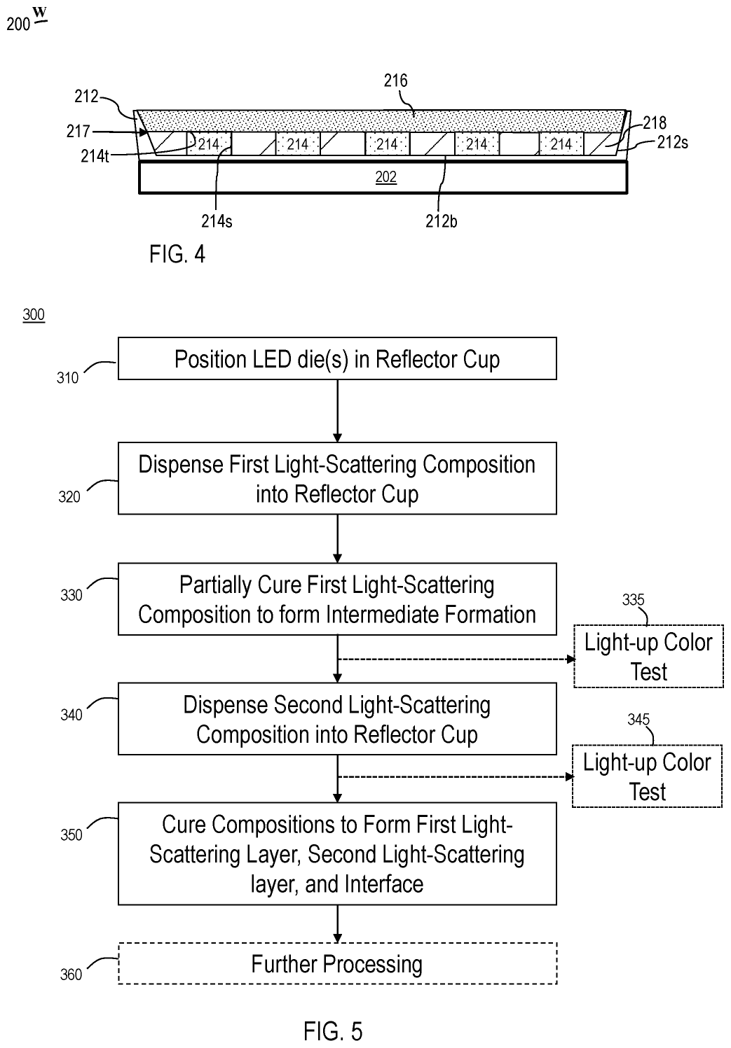

FIG. 4 is a cross-section schematic view of a light source 200 according to an embodiment. In embodiments, this configuration is a chip on board (COB) device. The light source device 200 comprises a plurality of LED dies 214 in a reflector cup (dam) 212, a first light scattering layer 218 and a second light-scattering layer 216. In one or more embodiments, the reflector cup (dam) 212 is integral to a mount 202. The mount 202 includes other structures such as contact to put the LED dies into electrical communication with the mount 202. The first light-scattering layer 218 contacts side surfaces 214s of the LED dies 214, and the bottom wall 212b and the sidewall 212s of the reflector cup 212. The first light-scattering layer 218 comprises light-scattering particles and a first binder material. A second light-scattering layer 216, which includes phosphor particles, contacts at least the top surface 214t of the LED dies 214, and the first light-scattering layer 218 at an interface 217. The second light-scattering layer 216 comprises phosphor particles and a second binder material. In one or more embodiments, a chip on board (COB) configuration comprises the light source of FIG. 4 and a drive circuit in communication with the mount. The drive circuit is configured to provide current to the mount to illuminate the LED dies.

FIG. 5 is a process flow diagram of a method of making manufacturing a light emitting device (LED) 300 according to one or more embodiments. At operation 310, one or more LED dies are positioned in a reflector cup.

At operation 320, a first light-scattering composition is dispensed to a partial fill in the reflector cup. The first light-scattering composition is dispensed to below a top surface of the LED die(s).

At operation 330, the first light-scattering composition is partially cured to form an intermediate formation or structure. For example, a snap cure may be conducted at a temperature in a range of 120° C.-180° C. over a duration of about 5 to 10 minutes in order to stop flow of the composition.

Thereafter, optionally at operation 335, a light-up color test is conducted to review the quality of light emission. Should the light emission based on the first composition/layer be out of specification, color adjustment for the second composition/layer is possible.

At operation 340, a second light-scattering composition is dispensed into the reflector cup.

Optionally at operation 345, another light-up color test is conducted to review the quality of light emission. Should the light emission be out of specification, rework of the second composition is possible. In one or more embodiments, the second composition is removed and re-dispensed upon adjustment.

At operation 350, the second light-scattering composition and the intermediate formation or structure of the first light-scattering composition are cured. In one or more embodiments, the curing is conducted at a temperature in a range of 150° C.-180° C. over a duration of four to eight hours. The first and second light-scattering compositions are chosen to yield respective light-scattering layers upon cure. Upon completion, the first light-scattering layer and the second light-scattering layer are formed along with an interface therebetween.

At operation 360, optional further processing is performed. In one or more embodiments, further processing including formation of a passivation layer around a portion or the entirety of the array. In one or more embodiments, contacts are coupled to the structure, either directly or via another structure such as a mount or submount, for electrical connection to a circuit board or other substrate or device. In embodiments, the contacts may be electrically insulated from one another by a gap, which may be filled with a dielectric material.

In summary, methods herein comprise: of manufacturing a light emitting source comprising: positioning one or more LED dies in a reflector cup; dispensing a first light-scattering composition into the reflector cup, contacting side surfaces of the LED dies, and a bottom wall and a sidewall of the reflector cup, the first light-scattering layer comprising light-scattering particles and a first binder material; partially curing the first light-scattering composition to form an intermediate first light-scattering formation; dispensing a second light-scattering composition into the reflector cup, contacting at least a top surface of the LED die, the second light-scattering composition comprising phosphor particles and a second binder material; and curing the intermediate first light-scattering formation and the second light-scattering composition to form a first light-scattering layer and a second light-scattering layer, respectively, and an interface therebetween.

### EXAMPLES

### Comparative Example A

A phosphor-converted light emitting diode (pc-LED) device was prepared in a conventional manner to yield a device according to FIG. 1 (prior art). A reflector cup including a blue-LED die was filled with a phosphor composition. The phosphor composition was cured a temperature in a range of 150° C.-180° C. over a duration of 4 hours to form a conventional phosphor layer. The phosphor composition comprised phosphor particles dispersed in a silicone polymer.

### Example 1

An inventive phosphor-converted light emitting diode (pc-LED) device was prepared to yield a device according to FIGS. 2-3. A reflector cup of the same dimensions as Comparative A and including a blue-LED die the same as provided in Comparative A was first partially filled with a first light-scattering composition. The first light-scattering composition was snap cured for 5-10 minutes at a temperature of 150° C. The reflector cup was then filled to slightly below a top edge of the cup with a second light-scattering composition. Thereafter the device was finally cured. Curing conditions were the same as in Comparative A.

The second light-scattering composition was the same as the phosphor composition of Comparative A. The first light-scattering composition was a diluted form of the second light-scattering composition in that the first light-scattering composition had one-third of the particle loading as compared to the second light-scattering composition.

### Example 2

### Testing

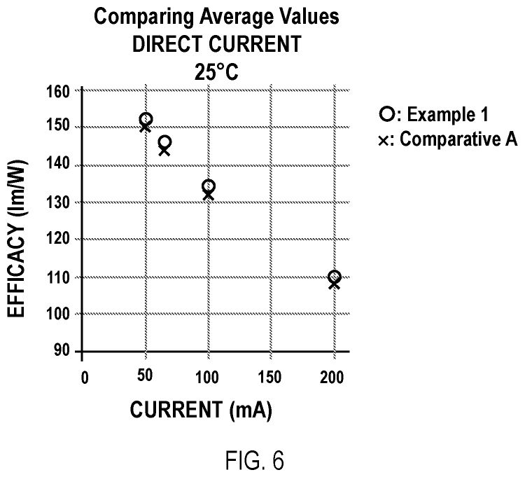

FIG. 6 provides a graph of efficacy (lm/W) versus (direct) current (mA) (averaged values) for Comparative A and Example 1 at 25° C. Increased efficiency is observed for the LED device of Example 1 relative to Comparative A.

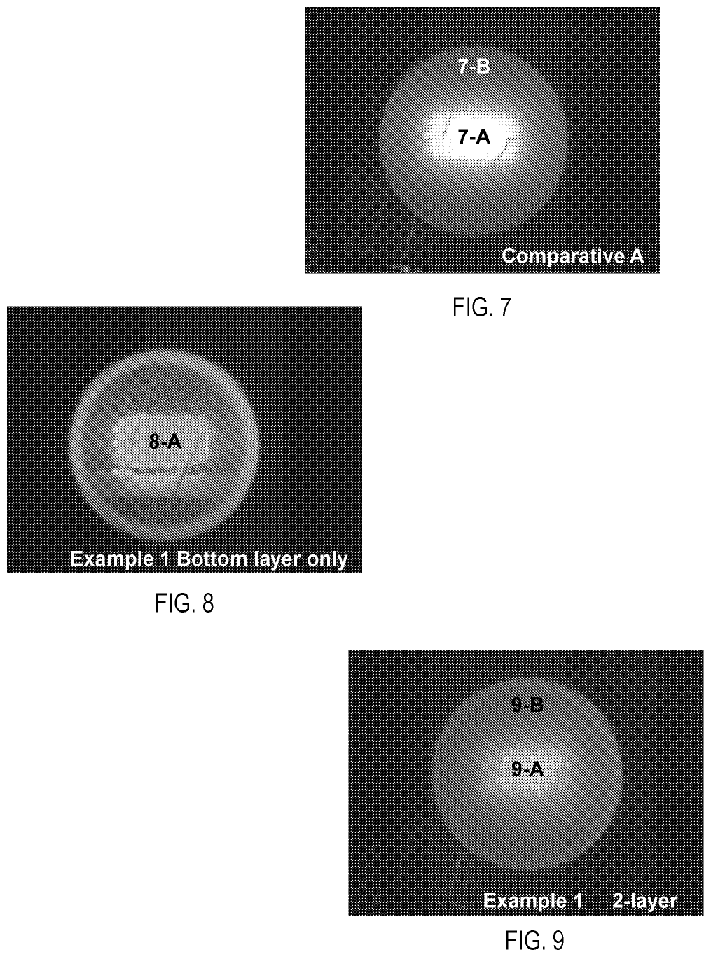

FIG. 7 is a top view photograph of the LED device of Comparative A. The circular area is the reflector cup and is the area of light emission. There is a bright area “7-A” above the LED die. There are dim areas “7-B” along the periphery, which are due to long side light paths. The device sidewall reflection is washed out because of strong absorption within the conventional phosphor layer.

FIG. 8 is a top view photograph of the LED device of Example 1 after the first light-scattering composition is partially cured. The glowing area surrounding “8-A” indicates that a reduced particle loading in the first light-scattering composition effectively redirected side light upwards.

FIG. 9 is a top view photograph of the completed LED device of Example 1.

The LED device of Example 1 shows more uniform intensity distribution across the device relative to Comparative A. In FIG. 9, the bright area is 9-A but is not a distinct boundary from an edge of the LED die towards the periphery 9-B. Side light reaches to package sidewall because of reduced absorption in the slurry and gets reflected upwards.

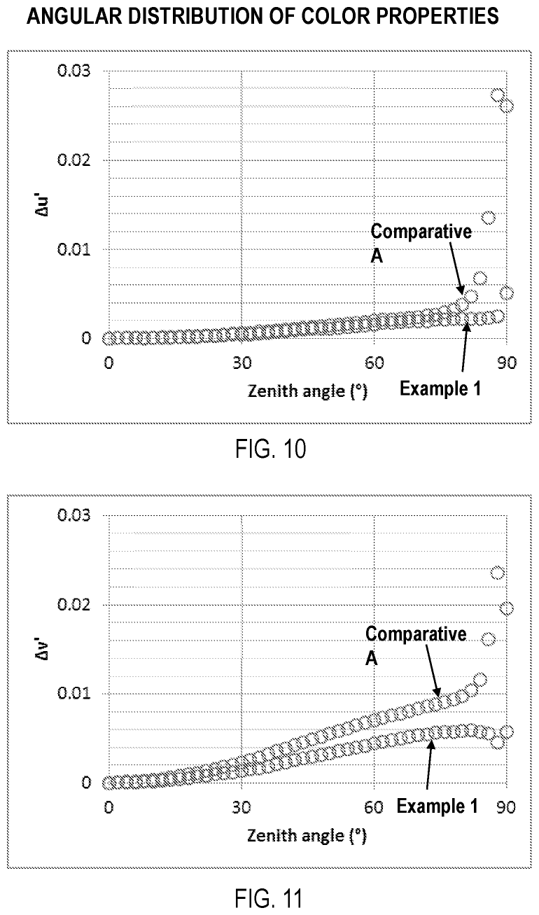

FIG. 10 is a graph of Δu′ versus Zenith angle (°), and FIG. 11 is a graph of Δv′ versus Zenith angle (°) for Comparative A and Example 1. The device of Example 1 showed improved angular distribution, that is, less variation.

Table 1 provides a measure for near-field (e.g., device surface) color distribution at two angles: 0° and 45° for Comparative A and Example 1. As the value decreases, color uniformity increases.

TABLE 1
Color distribution.

| | Comparative A | Example 1 |
|---|---|---|
| At 0° | 62 | 29 |
| At 45° | 57 | 24 |

Color variation over the inventive device of Example 1 was less by half in the u′-v′ color space relative to the device of Comparative A. As such, in one or more embodiments, devices herein comprise a color variation characteristic of v′ versus u′ that has a lower variation with respect to v′ as compared to a baseline color variation characteristic of a baseline LED device comprising a light emitting diode device including only a second light-scattering laying filling the reflector cup, in the absence of a first light-scattering layer in the reflector cup.

### Embodiments

Various embodiments are listed below. It will be understood that the embodiments listed below may be combined with all aspects and other embodiments in accordance with the scope of the invention.

Embodiment (a). A light emitting device comprising: a light emitting diode (LED) die in a reflector cup; a first light-scattering layer contacting a side surface of the LED die, and a bottom wall and a sidewall of the reflector cup, the first light-scattering layer comprising light-scattering particles and a first binder material; and a second light-scattering layer contacting at least a top surface of the LED die and the first light-scattering layer at an interface, the second light-scattering layer comprising phosphor particles and a second binder material.

Embodiment (b). The light emitting device of embodiment (a), wherein a combination of the first light-scattering layer and the second light-scattering layer fills the reflector cup around the LED die.

Embodiment (c). The light emitting device of embodiment (a) or (b), wherein the first light-scattering layer and the second light-scattering layer differ with respect to one or more of the following characteristics: kinematic viscosity at 25° C.; refractive index; type of particles: the light-scattering particles of the first light-scattering layer and the phosphor particles of the second light-scattering layer are different materials; type of binder material: the first binder of the first light-scattering layer and the second binder material of the second light-scattering layer are different materials; and particles loading: a first weight or volume ratio of the light-scattering particles of the first light-scattering layer to the first binder material differs from a second weight or volume ratio of the phosphor particles of the second light-scattering layer to the second binder material.

Embodiment (d). The light emitting device of any of embodiments (a) to (c), wherein the light-scattering particles of the first light-scattering layer and the phosphor particles of the second light-scattering layer are the same material, and a first concentration of the particles of the first light-scattering layer is less than a concentration of the particles of the second light-scattering layer.

Embodiment (e). The light emitting device of any of embodiments (a) to (d), wherein the reflector cup has an aspect ratio (width to height) of in a range of 2.5:1 to 60:1.

Embodiment (f). The light emitting device of any of embodiments (a) to (e), wherein the second light-scattering layer contacts the side surface of the LED die.

Embodiment (g). The light emitting device of any of embodiments (a) to (e), wherein the first and second binder materials are the same material.

Embodiment (h). The light emitting device of any of embodiments (a) to (e), wherein the first and second binder materials independently comprises a silicone polymer.

Embodiment (i). The light emitting device of any of embodiments (a) to (h), wherein the light-scattering particles of the first light-scattering layer and the phosphor particles of the second light-scattering layer are different materials.

Embodiment (j). The light emitting device of embodiment (i), wherein the light-scattering particles of the first light-scattering layer comprise one or more of: silica, titania, sapphire, and alumina; and the phosphor particles of the second light-scattering layer comprise yellow-emitting wavelength converting material, or green and red emitting wavelength converting materials.

Embodiment (k). The light emitting device of any of embodiments (a) to (j), wherein the LED die emits blue light and wherein the phosphor particles of the second light-scattering composition emits a light that, combined with the blue light, creates a white light.

Embodiment (l). A light source comprising: one or more light emitting diode (LED) dies in a reflector cup; a first light-scattering layer contacting side surfaces of the one or more LED dies, and a bottom wall and a sidewall of the reflector cup, the first light-scattering layer comprising light-scattering particles and a first binder material; and a second light-scattering layer spanning a width of the reflector cup, and the first light-scattering layer at an interface, the second light-scattering layer comprising phosphor particles and a second binder material; wherein a combination of the first light-scattering layer and the second light-scattering layer fills the reflector cup around the one or more LED dies; and the light-scattering particles of the first light-scattering layer and the phosphor particles of the second light-scattering layer are the same material, and a first concentration of the particles of the first light-scattering layer is less than a concentration of the particles of the second light-scattering layer.

Embodiment (m). The light source of embodiment (l), wherein the reflector cup has an aspect ratio (width to height) of in a range of 2.5:1 to 60:1.

Embodiment (n). The light source of embodiment (l) or (m) further comprising a mount to which the reflector cup is affixed; and a drive circuit in communication with the mount, the drive circuit configured to provide current to the mount to illuminate the LED dies.

Embodiment (o). The light source of any of embodiments (l) to (n), wherein the second light-scattering layer is in contact with at least a top surface of the one or more LED dies.

Embodiment (p). The light source of any of embodiments (l) to (n), wherein the first light-scattering layer is in contact with at least a top surface of the one or more LED dies.

Embodiment (q). A method of manufacturing a light emitting device comprising: positioning one or more light emitting diode (LED) dies in a reflector cup; dispensing a first light-scattering composition into the reflector cup, contacting side surfaces of the one or more LED dies, and a bottom wall and a sidewall of the reflector cup, the first light-scattering layer comprising light-scattering particles and a first binder material; partially curing the first light-scattering composition to form an intermediate first light-scattering formation; dispensing a second light-scattering composition into the reflector cup, the second light-scattering composition comprising phosphor particles and a second binder material; and curing the intermediate first light-scattering formation and the second light-scattering composition to form a first light-scattering layer and a second light-scattering layer, respectively, and an interface therebetween.

Embodiment (r). The method of embodiment (q), wherein a combination of the first light-scattering layer and the second light-scattering layer fills the reflector cup around the one or more LED dies.

Embodiment(s). The method of embodiment (q) or (r), wherein the light-scattering particles of the first light-scattering composition and the phosphor particles of the second light-scattering composition are the same material, and a first concentration of the particles of the first light-scattering composition is less than a concentration of the particles of the second light-scattering composition.

Embodiment (t). The method of any of embodiments (q) to(s), wherein the reflector cup has an aspect ratio (width to height) of in a range of 2.5:1 to 60:1.

Embodiment (u). The method of any of embodiments (q) to (t), wherein the first light-scattering layer and the second light-scattering layer differ with respect to one or more of the following characteristics: kinematic viscosity at 25° C.; refractive index; type of particles: the light-scattering particles of the first light-scattering layer and the phosphor particles of the second light-scattering layer are the same material; type of binder material; and particles loading: a first weight or volume ratio of the light-scattering particles of the first light-scattering layer to the first binder material differs from a second weight or volume ratio of the phosphor particles of the second light-scattering layer to the second binder material.

Embodiment (v). The method of any of embodiments (q) to (u), wherein the second light-scattering layer is in contact with at least a top surface of the one or more LED dies.

Embodiment (w). The method of any of embodiments (q) to (u), wherein the first light-scattering layer is in contact with at least a top surface of the one or more LED dies.

Embodiment (x). Any of embodiments (a) to (w) comprising a color variation characteristic of v′ versus u′ that has a lower variation with respect to v′ as compared to a baseline color variation characteristic of a baseline LED device comprising a light emitting diode device including only a second light-scattering laying filling the reflector cup, in the absence of a first light-scattering layer in the reflector cup.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims. It is also understood that other embodiments of this invention may be practiced in the absence of an element/step not specifically disclosed herein.

What is claimed is:

1. A light emitting device comprising:
a light emitting diode (LED) die in a reflector cup;
a first light-scattering layer contacting a side surface of the LED die, and a bottom wall and a sidewall of the reflector cup, the first light-scattering layer comprising light-scattering particles and a first binder material; and
a second light-scattering layer contacting at least a top surface of the LED die and the first light-scattering layer at an interface, the second light-scattering layer comprising phosphor particles and a second binder material.

2. The light emitting device of claim 1, wherein a combination of the first light-scattering layer and the second light-scattering layer fills the reflector cup around the LED die.

3. The light emitting device of claim 1, wherein the first light-scattering layer and the second light-scattering layer differ with respect to one or more of the following characteristics:
kinematic viscosity at 25° C.;
refractive index;
type of particles: the light-scattering particles of the first light-scattering layer and the phosphor particles of the second light-scattering layer are different materials;
type of binder material: the first binder of the first light-scattering layer and the second binder material of the second light-scattering layer are different materials; and
particles loading: a first weight or volume ratio of the light-scattering particles of the first light-scattering layer to the first binder material differs from a second weight or volume ratio of the phosphor particles of the second light-scattering layer to the second binder material.

4. The light emitting device of claim 1, wherein the light-scattering particles of the first light-scattering layer and the phosphor particles of the second light-scattering layer are the same material, and a first concentration of the particles of the first light-scattering layer is less than a concentration of the particles of the second light-scattering layer.

5. The light emitting device of claim 1, wherein the reflector cup has an aspect ratio (width to height) of in a range of 2.5:1 to 60:1.

6. The light emitting device of claim 1, wherein the second light-scattering layer contacts the side surface of the LED die.

7. The light emitting device of claim 1, wherein the first and second binder materials are the same material.

8. The light emitting device of claim 1, wherein the first and second binder materials independently comprises a silicone polymer.

9. The light emitting device of claim 1, wherein the light-scattering particles of the first light-scattering layer and the phosphor particles of the second light-scattering layer are different materials.

10. The light emitting device of claim 9, wherein the light-scattering particles of the first light-scattering layer comprise one or more of: silica, titania, sapphire, and alumina; and the phosphor particles of the second light-scattering layer comprise yellow-emitting wavelength converting material, or green and red emitting wavelength converting materials.

11. The light emitting device of claim 1, wherein the LED die emits blue light and wherein the phosphor particles of the second light-scattering composition emits a light that, combined with the blue light, creates a white light.

12. A light source comprising:
one or more light emitting diode (LED) dies in a reflector cup;
a first light-scattering layer contacting side surfaces of the one or more LED dies, and a bottom wall and a sidewall of the reflector cup, the first light-scattering layer comprising light-scattering particles and a first binder material; and
a second light-scattering layer spanning a width of the reflector cup, and the first light-scattering layer at an interface, the second light-scattering layer comprising phosphor particles and a second binder material;
wherein a combination of the first light-scattering layer and the second light-scattering layer fills the reflector cup around the one or more LED dies; and the light-scattering particles of the first light-scattering layer and the phosphor particles of the second light-scattering layer are the same material, and a first concentration of the particles of the first light-scattering layer is less than a concentration of the particles of the second light-scattering layer.

13. The light source of claim 12, wherein the reflector cup has an aspect ratio (width to height) of in a range of 2.5:1 to 60:1.

14. The light source of claim 12 further comprising a mount to which the reflector cup is affixed; and a drive circuit in communication with the mount, the drive circuit configured to provide current to the mount to illuminate the LED dies.

15. The light source of claim 13, wherein the second light-scattering layer is in contact with at least a top surface of the one or more LED dies.

16. The light source of claim 13, wherein the first light-scattering layer is in contact with at least a top surface of the one or more LED dies.

17. A method of manufacturing a light emitting device comprising:
positioning one or more light emitting diode (LED) dies in a reflector cup;
dispensing a first light-scattering composition into the reflector cup, contacting side surfaces of the one or more LED dies, and a bottom wall and a sidewall of the reflector cup, the first light-scattering layer comprising light-scattering particles and a first binder material;
partially curing the first light-scattering composition to form an intermediate first light-scattering formation;
dispensing a second light-scattering composition into the reflector cup, the second light-scattering composition comprising phosphor particles and a second binder material; and
curing the intermediate first light-scattering formation and the second light-scattering composition to form a first light-scattering layer and a second light-scattering layer, respectively, and an interface therebetween.

18. The method of claim 17, wherein the light-scattering particles of the first light-scattering composition and the phosphor particles of the second light-scattering composition are the same material, and a first concentration of the particles of the first light-scattering composition is less than a concentration of the particles of the second light-scattering composition.

19. The method of claim 17, wherein the reflector cup has an aspect ratio (width to height) of in a range of 2.5:1 to 60:1.

20. The method of claim 17, wherein the first light-scattering layer and the second light-scattering layer differ with respect to one or more of the following characteristics:
kinematic viscosity at 25° C.;
refractive index;
type of particles: the light-scattering particles of the first light-scattering layer and the phosphor particles of the second light-scattering layer are the same material;
type of binder material; and
particles loading: a first weight or volume ratio of the light-scattering particles of the first light-scattering layer to the first binder material differs from a second weight or volume ratio of the phosphor particles of the second light-scattering layer to the second binder material.
